(19) United States
(12) Patent Application Publication
(10) Pub. No.: US 2021/0043549 A1
(43) Pub. Date: Feb. 11, 2021

(54) CLIPS FOR SEMICONDUCTOR PACKAGES

(71) Applicant: Infineon Technologies AG, Neubiberg (DE)

(72) Inventors: Ke Yan Tean, Melaka (MY); Mei Fen Hiew, Melaka (MY); Jia Yi Wong, Melaka (MY)

(73) Assignee: Infineon Technologies AG, Neubiberg (DE)

(21) Appl. No.: 16/535,632

(22) Filed: Aug. 8, 2019

(51) Int. Cl. H01L 23/495; H01L 23/00; H01L 23/31

(52) U.S. Cl. CPC H01L 23/49517; H01L 23/49568; H01L 24/40; H01L 23/3107; H01L 2224/352; H01L 23/49537; H01L 23/49575; H01L 2224/40175; H01L 2224/4005; H01L 24/35

(57) ABSTRACT

A clip for a semiconductor package includes a first portion and a second portion. The first portion includes a first surface, a second surface opposite to the first surface and configured to contact a first electrically conductive component, and a stepped region between the first surface and the second surface such that the second surface has a smaller area than the first surface. The second portion is coupled to the first portion and configured to contact a second electrically conductive component. The second portion includes a third surface aligned with the first surface.

### BACKGROUND

A clip may be used to electrically couple components of a semiconductor package to each other, such as a semiconductor die to a lead frame. Semiconductor packages including a down set clip inside the package may be ineffective in dissipating heat out from the package. A heat slug may be attached to the clip to assist in dissipating heat out from the package. Attaching the heat slug, however, adds additional fabrication steps and may still not provide sufficient heat dissipation due to the size of the semiconductor die and/or the location of the heat slug with respect to the semiconductor die.

In metalworking, rolling is a metal forming process in which metal stock is passed through one or more pairs of rolls to reduce the thickness and to make the thickness uniform. If the temperature of the metal is below its recrystallization temperature, the process is known as cold rolling. It also improves the surface finish and holds tighter tolerances. Commonly cold-rolled products include sheets, strips, bars, and rods.

Milling is the process of machining using rotary cutters to remove material by advancing a cutter into a workpiece. This may be done varying direction on one or several axes, cutter head speed, and pressure. Milling is one of the most commonly used processes for machining custom parts to precise tolerances.

Coining is a form of precision stamping in which a workpiece is subjected to a sufficiently high stress to induce plastic flow on the surface of the material. A beneficial feature is that in some metals, the plastic flow reduces surface grain size, and work hardens the surface, while the material deeper in the part retains its toughness and ductility. Coining is used to manufacture parts for all industries and is commonly used when high relief or very fine features are required. For example, it may be used to produce precision parts with small or polished surface features.

Coining is a cold working process similar in other respects to forging, which takes place at elevated temperature; it uses a great deal of force to plastically deform a workpiece, so that it conforms to a die. Coining can be done using a gear driven press, a mechanical press, or more commonly, a hydraulically actuated press. Coining typically requires higher tonnage presses than stamping, because the workpiece is plastically deformed and not actually cut, as in some other forms of stamping.

For these and other reasons, a need exists for the present disclosure.

### SUMMARY

One example of a clip for a semiconductor package includes a first portion and a second portion. The first portion includes a first surface, a second surface opposite to the first surface and configured to contact a first electrically conductive component, and a stepped region between the first surface and the second surface such that the second surface has a smaller area than the first surface. The second portion is coupled to the first portion and configured to contact a second electrically conductive component. The second portion includes a third surface aligned with the first surface.

One example of a semiconductor package includes a first electrically conductive component, a second electrically conductive component, and a clip. The clip electrically couples the first electrically conductive component to the second electrically conductive component. The clip includes a first portion and a second portion. The first portion includes a first surface, a second surface coupled to the first electrically conductive component, a first thickness between the first surface and the second surface, and a stepped region between the first surface and the second surface such that the second surface has a smaller area than the first surface. The second portion is coupled to the first portion and the second electrically conductive component. The second portion includes a third surface, a fourth surface, and a second thickness between the third surface and the fourth surface less than the first thickness. The third surface is aligned with the first surface.

One example of a method for fabricating a clip for a semiconductor package includes metalworking a single gauge clip precursor to form a dual gauge clip precursor comprising a thin portion and a thick portion. The method includes coining the thick portion of the dual gauge clip precursor to form a clip including a stepped region between a first surface and a second surface opposite to the first surface such that the second surface has a smaller area than the first surface.

### BRIEF DESCRIPTION OF THE DRAWINGS

FIGS. 1A and 1B illustrate one example of a clip for a semiconductor package.

FIGS. 2A and 2B illustrate another example of a clip for a semiconductor package.

FIGS. 3A and 3B illustrate example semiconductor packages including a clip.

FIG. 4 illustrates an enlarged view of one example of a portion of a semiconductor package including a clip.

FIGS. 5A-5D illustrate various views of examples of a semiconductor package including a clip.

FIGS. 6A and 6B illustrate another example of a semiconductor package including a clip.

FIGS. 7A-7C illustrate one example of a method for fabricating a clip for a semiconductor package.

### DETAILED DESCRIPTION

In the following detailed description, reference is made to the accompanying drawings which form a part hereof, and in which is shown by way of illustration specific examples in which the disclosure may be practiced. It is to be understood that other examples may be utilized and structural or logical changes may be made without departing from the scope of the present disclosure. The following detailed description, therefore, is not to be taken in a limiting sense, and the scope of the present disclosure is defined by the appended claims. It is to be understood that features of the various examples described herein may be combined, in part or whole, with each other, unless specifically noted otherwise.

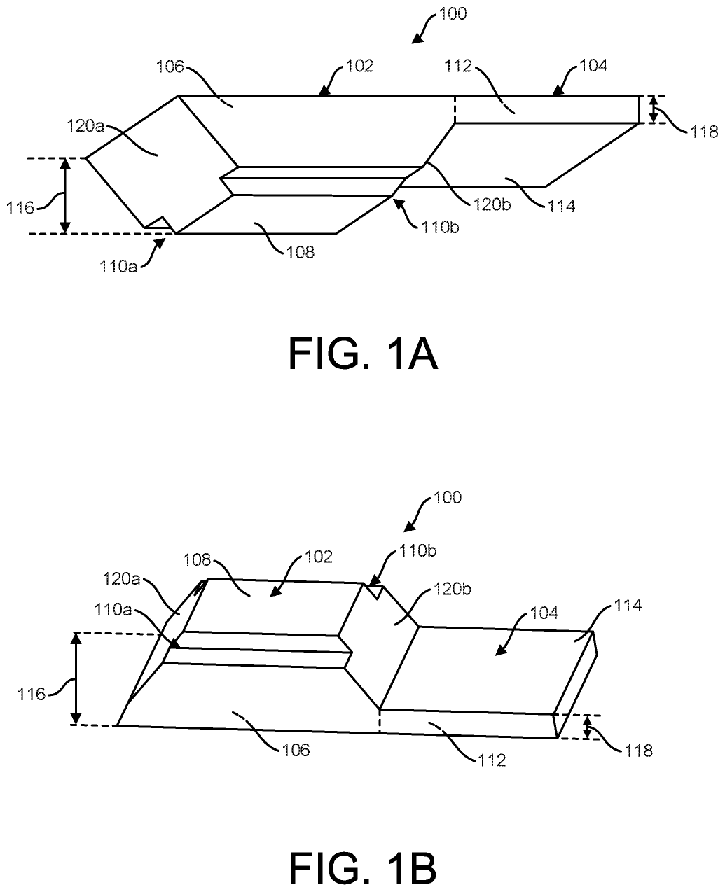

FIGS. 1A and 1B illustrate one example of a clip 100 for a semiconductor package. Clip 100 is made of a metal and may be plated. Clip 100 may include copper, aluminum, gold, or another suitable metal or combination of metals. Clip 100 includes a first portion 102 and a second portion 104. The first portion 102 includes a first surface 106 and a second surface 108 opposite to the first surface 106. The second surface 108 is configured to contact a first electrically conductive component, such as a first die, a first lead frame, a first carrier, or another suitable component.

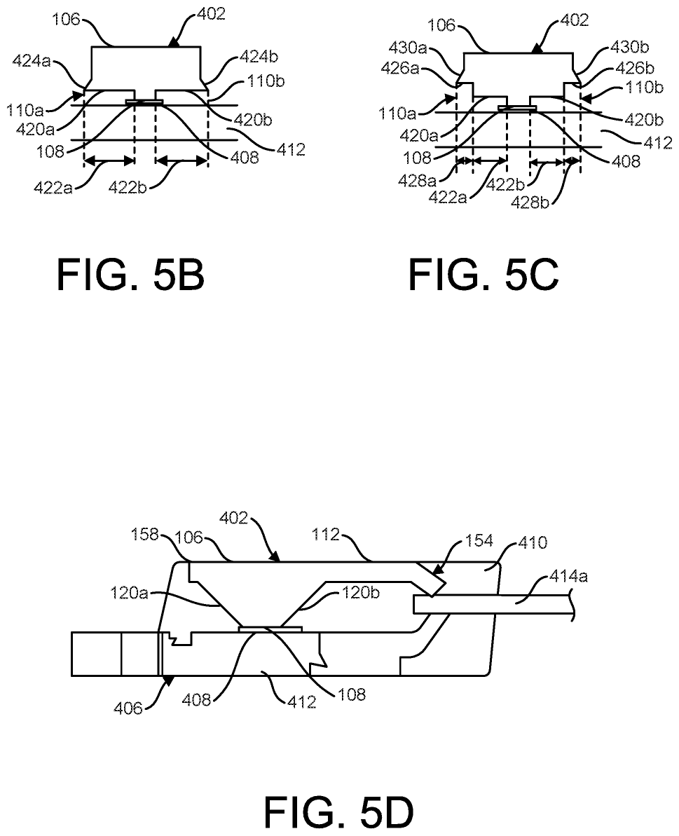

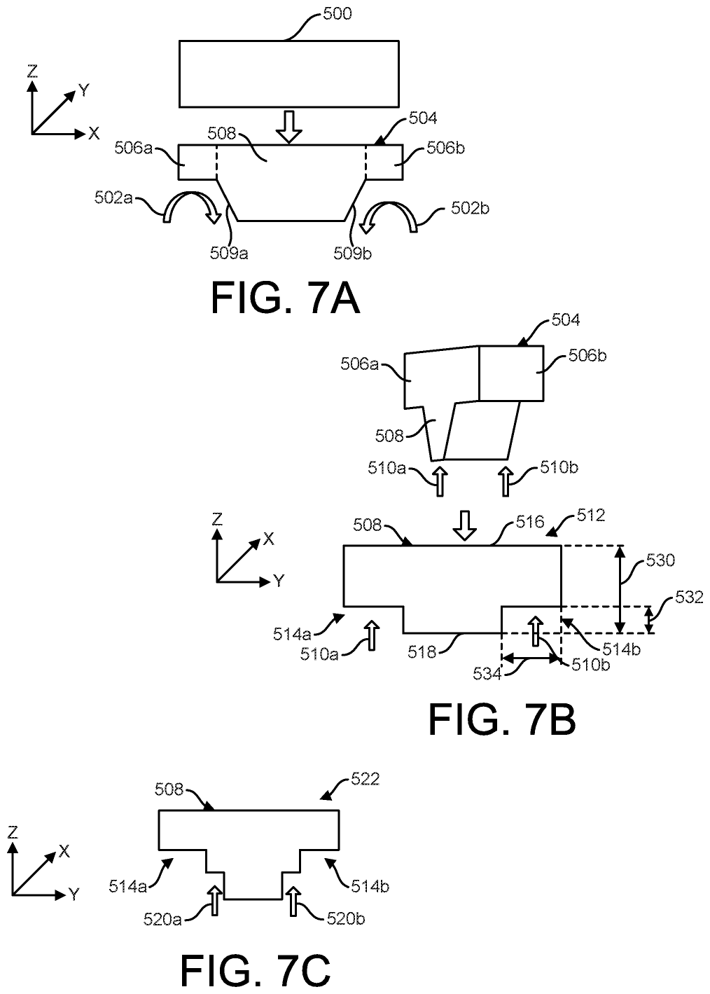

First portion 102 includes stepped regions 110a, 110b between the first surface 106 and the second surface 108 such that the second surface 108 has a smaller area than the first surface 106. In this example, each stepped region 110a, 110b includes a single step. In other examples as described below with reference to FIGS. 5C and 7C, each stepped region 110a, 110b may include a plurality of steps, such as two, three, four, or more steps. Each stepped region 110a, 110b may be configured such that the area of the second surface 108 is sized to contact a contact pad of a die without shorting to adjacent contact pads. While in this example, stepped regions 110a, 110b have vertical sidewalls, in other examples stepped regions 110a, 110b may have sloped sidewalls.

The second portion 104 is coupled (e.g., integral with) the first portion 102. The second portion 104 is configured to contact a second electrically conductive component, such as a second die, a second lead frame, a second carrier, or another portion of the first lead frame (e.g., a lead of the first lead frame). In some embodiments, the second electrically conductive component may not necessary be a part of the common product including the first electrically conductive component. For example, the second portion 104 itself can be formed in the shape of a lead, so that it can be used to contact a different product, such as another semiconductor package, a printed circuit board (PCB), etc. Accordingly, clip 100 is configured to electrically couple a first electrically conductive component to a second electrically conductive component. The second portion 104 includes a third surface 112 and a fourth surface 114 opposite to the third surface 112. The third surface 112 is aligned with the first surface 106. Accordingly, the first surface 106 and the third surface 112 form a common surface.

The first portion 102 includes a first thickness 116 between the first surface 106 and the second surface 108. The second portion 104 includes a second thickness 118 between the third surface 112 and the fourth surface 114. The second thickness 118 is less than the first thickness 116. First portion 102 includes sloped surfaces 120a, 120b between the first surface 106 and the second surface 108. In particular, the sloped surface 120a extends fully between the first surface 106 and the second surface 108, while the sloped surface 120b extends fully between second surface 108 and the fourth surface 114. The sloped surfaces 120a, 120b in combination with the stepped regions 110a, 110b form a pyramid shaped first portion 102. Pyramid shaped first portion 102 improves the heat dissipation from a die when the second surface 108 of the clip 100 is attached to a die as explained in greater detail below.

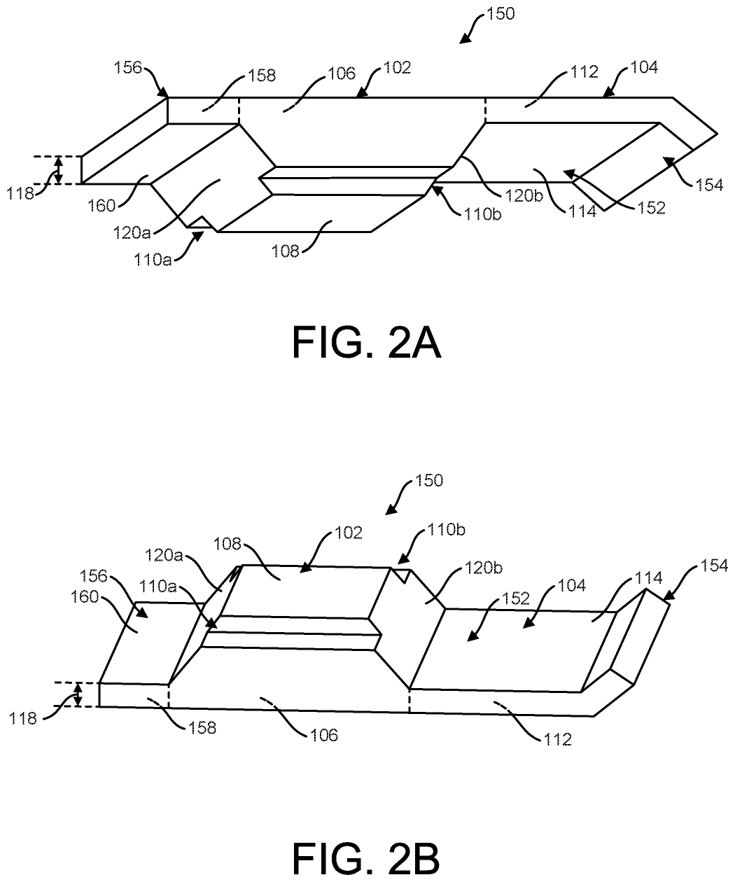

FIGS. 2A and 2B illustrate another example of a clip 150 for a semiconductor package. Clip 150 is similar to clip 100 previously described and illustrated with reference to FIGS. 1A and 1B, except that clip 150 includes a bent region 154 and a third portion 156. In this example, the second portion 104 includes a planar region 152 coupled to (e.g., integral with) the first portion 102 and the bent region 154 configured to contact the second electrically conductive component. Bent region 154 may have any suitable length and angle (i.e., from the planar region 152) to contact the second electrically conductive component. In some embodiments, the bent region 154 may be formed in the form of a lead, which may be used to contact a lead of a lead frame, another semiconductor product, a PCB, etc.

Third portion 156 is coupled (e.g., integral with) the first portion 102 opposite to the second portion 104. The third portion 156 includes a fifth surface 158 and a sixth surface 160 opposite to the fifth surface 158. In this example, the thickness between the fifth surface 158 and the sixth surface 160 is equal to the second thickness 118. In other examples, however, the thickness between the fifth surface 158 and the sixth surface 160 may be greater than the second thickness 118 or less than the second thickness 118. The fifth surface 158 is aligned with the first surface 106 and the third surface 112. Accordingly, the first surface 106, the third surface 112, and the fifth surface 158 form a common surface. One benefit of having the coplanar common surface is having a large surface, which can be exposed from a semiconductor package or attached to an external heat spreader, to improve the heat dissipation performance.

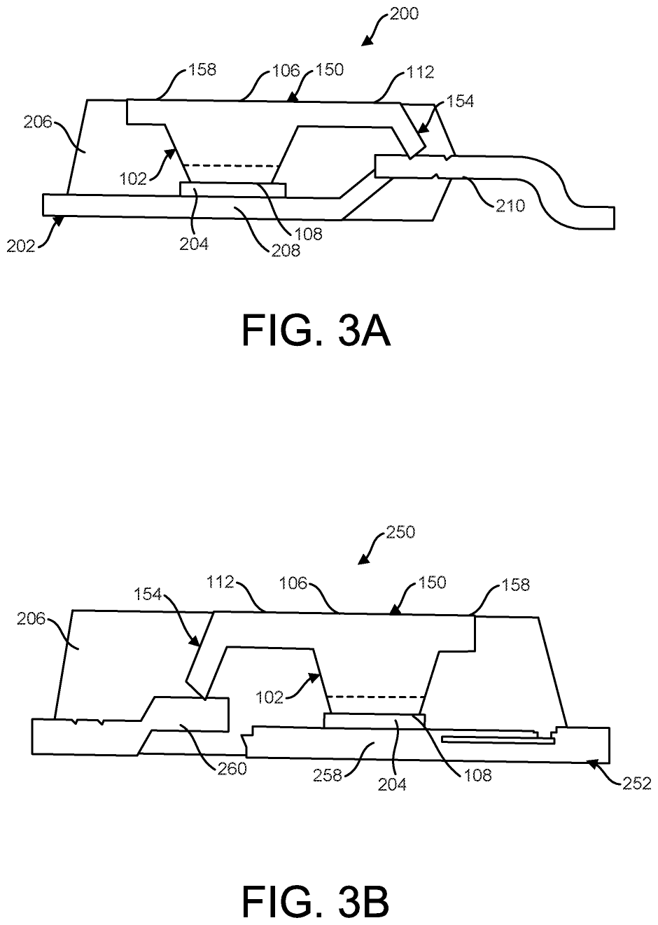

FIG. 3A illustrates one example of a semiconductor package 200 including a clip 150 as previously described and illustrated with reference to FIGS. 2A and 2B. In this example, semiconductor package 200 also includes a lead frame 202, a die 204, and a mold material 206. Lead frame 202 includes a die paddle 208 and a gullwing lead 210. Lead frame 202 is made of a metal or has a metal surface, such as Ag, Cu, Ni/Pd/Au, NiNiP, or Ni/Pd/AuAg. Die 204 is attached to die paddle 208 (e.g., via an adhesive material, solder, sinter, etc.). Die 204 may be a semiconductor die and may include silicon, silicon carbide, or another suitable semiconductor material. In some examples, die 204 may have a die area between about 4 mm² and about 8 mm². The second surface 108 of clip 150 is coupled to die 204 (e.g., via solder). The bent region 154 of clip 150 is coupled to lead 210 (e.g., via solder). Mold material 206 encapsulates at least portions of the lead frame 202, the die 204, and the clip 150 such that the common surface (i.e., first surface 106, third surface 112, and fifth surface 158) is exposed. Mold material 206 may include an epoxy or another suitable dielectric material. Pyramid shaped first portion 102 of clip 150 improves the heat dissipation from die 204 by dissipating heat from the die 204 towards the large exposed common surface 106, 112, 158, which acts to cool the die 204.

FIG. 3B illustrates another example of a semiconductor package 250 including a clip 150 as previously described and illustrated with reference to FIGS. 2A and 2B. Semiconductor device 250 is similar to semiconductor device 200 previously described and illustrated with reference to FIG. 3A, except that semiconductor package 250 is a leadless package. In this example, semiconductor package 250 also includes a lead frame 252, a die 204, and a mold material 206. Lead frame 252 includes a die paddle 258 and a lead 260. Lead frame 252 is made of a metal or has a metal surface, such as Ag, Cu, Ni/Pd/Au, NiNiP, or Ni/Pd/AuAg. Die 204 is attached to die paddle 258 (e.g., via an adhesive material, solder, sinter, etc.). The second surface 108 of clip 150 is coupled to die 204 (e.g., via solder). The bent region 154 of clip 150 is coupled to lead 260 (e.g., via solder). Mold material 206 encapsulates at least portions of the lead frame 252, the die 204, and the clip 150 such that the common surface (i.e., first surface 106, third surface 112, and fifth surface 158) is exposed. Pyramid shaped first portion 102 of clip 150 improves the heat dissipation from die 204 by dissipating heat from the die 204 towards the large exposed common surface 106, 112, 158, which acts to cool the die 204.

In some embodiments, when the size of the die 204 is very small, such as a SiC die, it is not easy to make a small contact surface of a metal clip (e.g., second surface 108) suitable for a very small die using traditional manufacturing methods. Another problem of traditional clips, made by traditional manufacturing methods, is that it is difficult to make a large top surface, which is exposable from the semiconductor package or attachable to an external heat spreader, while keeping the contact surface (e.g., second surface 108) small enough to attach to a small die. In other words, it is difficult to make a clip having the balance of having a small enough contact surface for attaching to a small die and having a large enough top surface for exposing from the semiconductor package or attaching to an external heat spreader. By using the pyramid shaped clip of some embodiments of the present disclosure, however, it is achievable to have a small contact surface for contacting a small die and a large top surface for heat dissipation performance, especially when using a stepped region (e.g., 110a, 110b).

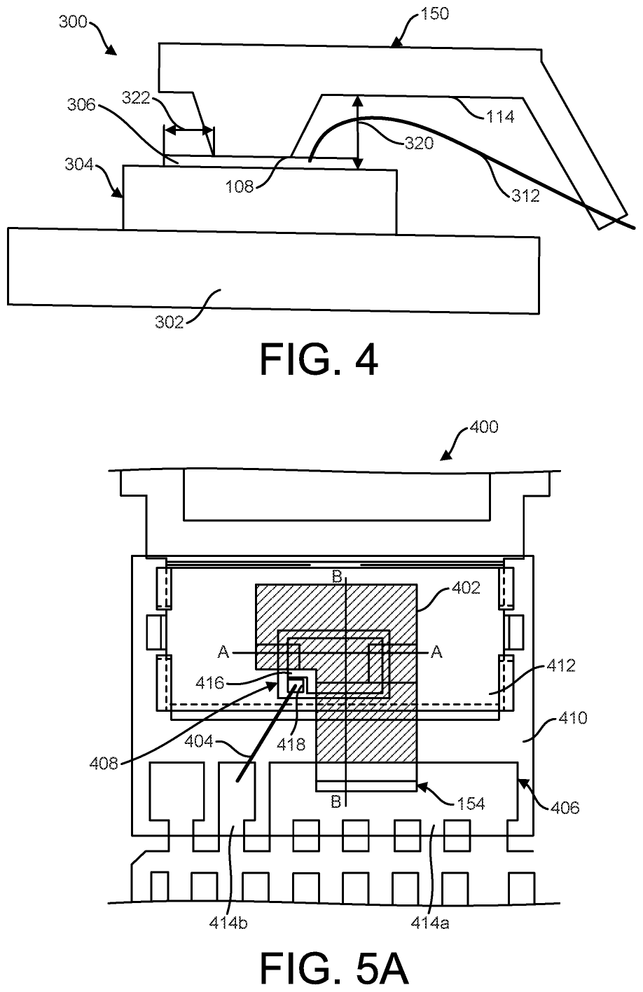

FIG. 4 illustrates an enlarged view of one example of a portion of a semiconductor package 300 including a clip 150. In this example, the portion of the semiconductor package 300 also includes a die paddle 302 and a die 304. Die 304 may be a semiconductor die and may include silicon, silicon carbide, or another suitable semiconductor material. In some examples, die 304 may have a die area between about 4 mm² and about 8 mm². Die 304 includes a contact pad 306. Die 304 is attached to die paddle 302 (e.g., via an adhesive material, solder, sinter, etc.). The contact pad 306 is electrically coupled to the first surface 108 of clip 150 (e.g., via solder). In some embodiments, a bond wire 312 may also be coupled to die 304.

In one example, die 304 is a silicon carbide (SiC) die and the distance 320 between the bottom surface of the contact pad 306 and the fourth surface 114 of clip 150 is equal to or greater than 0.3 mm. In one example, the distance 322 between the edge of the second surface 108 of clip 150 and the edge of contact pad 306 is equal to or greater than 0.1 mm. The distances 320 and 322 ensure the proper operation of die 304. Because of the existence of the stepped region in the clip, it is easier to make the smaller second surface 108, which can meet some design rules of semiconductor packages.

FIG. 5A illustrates a top view of a semiconductor package 400 including a section A-A and a section B-B. FIG. 5B illustrates a first example of section A-A of FIG. 5A, and FIG. 5C illustrates a second example of section A-A of FIG. 5A. FIG. 5D illustrates one example of section B-B of FIG. 5A. Referring to FIGS. 5A and 5D, semiconductor device 400 includes a clip 402, a bond wire 404, a lead frame 406, a die 408, and a mold material 410. Lead frame 406 includes a die paddle 412 and leads 414a, 414b. Lead frame 406 is made of a metal or has a metal surface, such as Ag, Cu, Ni/Pd/Au, NiNiP, or Ni/Pd/AuAg. Die 408 includes a first contact pad 416 and a second contact pad 418 on an upper side of the die. The bottom side of die 408 is attached to die paddle 412 (e.g., via an adhesive material, solder, sinter, etc.). Die 408 may be a semiconductor die and may include silicon, silicon carbide, or another suitable semiconductor material. In some examples, die 408 may have a die area between about 4 mm² and about 8 mm².

Clip 402 is similar to clip 150 previously described and illustrated with reference to FIGS. 2A-2B, including the first surface 106, the second surface 108, the third surface 112, the fourth surface 158, the sloped surfaces 120a, 120b, and the bent region 154. For clip 402, however, the first portion along section A-A is wider than the second portion. The second surface 108 of clip 402 is electrically coupled to the first contact pad 416 of die 408 (e.g., via solder). The bent region 154 of clip 402 is electrically coupled to lead 414a (e.g., via solder). Bond wire 404 is electrically coupled between the second contact pad 418 of die 408 and lead 414b. Mold material 410 encapsulates at least portions of the clip 402, the bond wire 404, the lead frame 406, and the die 408 such that the common surface (i.e., first surface 106, third surface 112, and fifth surface 158) of clip 402 is exposed. Mold material 410 may include an epoxy or another suitable dielectric material. In this example, the sloped surfaces 120a, 120b between the first surface 106 and the second surface 108 have substantially the same but opposite slopes. Sloped surfaces 120a, 120b may be fabricated using a rolling, milling, or hammering process as will be described below with reference to FIG. 7A.

FIG. 5B illustrates clip 402 with stepped regions 110a, 110b each having a single step 420a, 420b. The area of second surface 108 may be set based on the width 422a, 422b of each step 420a, 420b. In this example, the width 422a is substantially equal to the width 422b. In other examples, width 422a and width 422b may be different. Each step 420a, 420b may also include a protrusion 424a, 424b based on the process used to fabricate clip 402. Protrusions 424a, 424b improve the locking of the mold material within the semiconductor package. In this example, a single coining process may be used to form stepped regions 110a, 110b as will be described below with reference to FIG. 7B.

FIG. 5C illustrates clip 402 with stepped regions 110a, 110b each having first steps 420a, 420b and second steps 426a, 426b. The area of second surface 108 may be set based on the width 422a, 422b of each first step 420a, 420b and the width 428a, 428b of each second step 426a, 426b. In this example, the width 422a is substantially equal to the width 422b, and the width 428a is substantially equal to the width 428b. Also in this example, the width 428a, 428b of each second step 426a, 426b is less than the width 422a, 422b of each first step 420a, 420b. In other examples, however, the width 428a, 428b of each second step 426a, 426b may be equal to or greater than the width 422a, 422b of each first step 420a, 420b. Each second step 426a, 426b may also include a protrusion 430a, 430b based on the process used to fabricate clip 402. Protrusions 430a, 430b improve the locking of the mold material within the semiconductor package. In this example, a multiple coining process may be used to form stepped regions 110a, 110b as will be described below with reference to FIGS. 7B-7C.

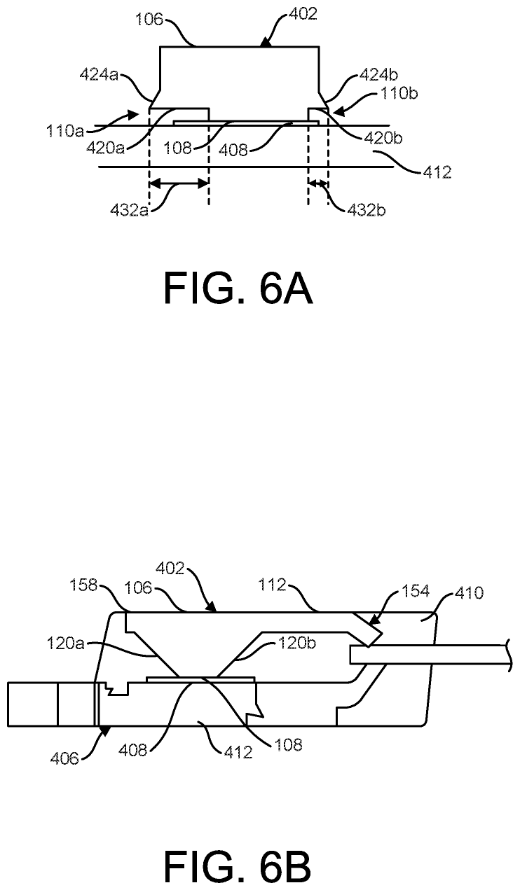

FIG. 6A illustrates a third example of section A-A of FIG. 5A, and FIG. 6B illustrates another example of section B-B of FIG. 5A. Referring to FIG. 6A, in this example clip 402 includes stepped regions 110a, 110b each having a single step 420a, 420b. The area of second surface 108 may be set based on the width 432a, 432b of each step 420a, 420b. In this example, the width 432a is greater than the width 432b. In other examples, however, the width 432b may be greater than the width 432a. Each step 420a, 420b may also include the protrusion 424a, 424b based on the process used to fabricate clip 402. In this example, a single coining process may be used to form stepped regions 110a, 110b as will be described below with reference to FIG. 7B. Also, in this example, as illustrated in FIG. 6B, the sloped surfaces 120a, 120b between the first surface 106 and the second surface 108 have different slopes such that sloped surface 120a is more vertical than sloped surface 120b. Sloped surfaces 120a, 120b may be fabricated using a rolling, milling, or hammering process as will be described below with reference to FIG. 7A.

FIGS. 7A-7C illustrate one example of a method for fabricating a clip for a semiconductor package, such as clip 100, 150, or 402 previously described and illustrated with reference to FIGS. 1A-6B. As illustrated in FIG. 7A, a single gauge clip precursor 500 is formed via metalworking as indicated at 502a, 502b (e.g., via rolling, milling, hammering, etc.) to form a dual gauge clip precursor 504 including a thin portion 506a, 506b and a thick portion 508. The single gauge clip precursor 500 may have a substantially a rectangular shape, such as for clip 100 or 150, or an L-shape, such as for clip 402.

In one example, metalworking the single gauge clip precursor 500 to form the dual gauge clip precursor 504 includes metalworking opposing sides of the single gauge clip precursor to form the thick portion 508 with opposing sloped sidewalls 509a, 509b. In some examples, metalworking the single gauge clip precursor 500 to form the dual gauge clip precursor 504 includes metalworking the single gauge clip precursor 500 to form the thick portion 508 between a first thin portion 506a and a second thin portion 506b larger than the first thin portion 506a (e.g., see thick first portion 102 between thin second portion 104 and thin third portion 156 of clip 150 of FIGS. 2A-2B).

As illustrated in FIG. 7B, the thick portion 508 of the dual gauge clip precursor 504 is coined as indicated at 510a, 510b to form a clip 512 including stepped regions 514a, 514b between a first surface 516 and a second surface 518 opposite to the first surface 516 such that the second surface 518 has a smaller area than the first surface 516. In one example, where the thickness 530 of thick portion 508 is 0.25 mm, the coining depth 532 may be up to 0.1 mm and the coining width 534 is at least 0.1 mm. In another example, where the thickness 530 of thick portion 508 is 0.5 mm, the coining depth 532 may be up to 0.2 mm and the coining width 534 is at least 0.1 mm. In yet another example, where the thickness 530 of thick portion 508 is 1.27 mm, the coining depth 532 may be up to 0.4 mm and the coining width 534 is at least 0.1 mm.

In some examples, coining may also be used to form a clip including stepped regions perpendicular to stepped regions 514a, 514b, such that the clip will include four stepped regions. For example, for semiconductor package 400 of FIG. 5A, clip 402 may be formed via coining to include stepped regions along the A-A direction and additional stepped regions along the B-B direction.

Coining has the benefit of being capable of achieving the desired clip contact area and size to adapt to different die sizes while meeting clearance requirements. The clearance requirements prevent electrical breakdown between two different electric potentials. Multistep coining may be used to achieve an even smaller contact area while meeting the clearance requirements for especially small die sizes.

As illustrated in FIG. 7C, coining the thick portion 508 of the dual gauge clip precursor 504 may include multiple coining of the thick portion 508, as indicated at 510a, 510b in FIG. 7B and at 520a, 520b in FIG. 7C, to form a clip 522 including a plurality of steps in the stepped regions 514a, 514b. While FIGS. 7B and 7C illustrate stepped regions 514a and 514b, in other examples, coining may be used to form a single stepped region 514a or 514b, or four stepped regions.

Although specific examples have been illustrated and described herein, a variety of alternate and/or equivalent implementations may be substituted for the specific examples shown and described without departing from the scope of the present disclosure. This application is intended to cover any adaptations or variations of the specific examples discussed herein. Therefore, it is intended that this disclosure be limited only by the claims and the equivalents thereof.

1. A clip for a semiconductor package, the clip comprising:
a first portion comprising a first surface, a second surface opposite to the first surface and configured to contact a first electrically conductive component, and a stepped region between the first surface and the second surface such that the second surface has a smaller area than the first surface; and
a second portion coupled to the first portion and configured to contact a second electrically conductive component, the second portion comprising a third surface aligned with the first surface.

2. The clip of claim 1, wherein the first portion comprises a first thickness between the first surface and the second surface, and
wherein the second portion comprises a fourth surface opposite to the third surface and a second thickness between the third surface and the fourth surface less than the first thickness.

3. The clip of claim 1, wherein the stepped region comprises a single step.

4. The clip of claim 1, wherein the stepped region comprises a plurality of steps.

5. The clip of claim 1, wherein the first portion comprises a sloped surface between the first surface and the second surface.

6. The clip of claim 1, wherein the first portion is pyramid shaped.

7. The clip of claim 1, wherein the second portion comprises a planar region coupled to the first portion and a bent region configured to contact the second electrically conductive component.

8. The clip of claim 1, further comprising:
a third portion coupled to the first portion opposite to the second portion, the third portion comprising a fifth surface, a sixth surface opposite to the fifth surface, and the second thickness between the fifth surface and the sixth surface, the fifth surface aligned with the first surface.

9. A semiconductor package comprising:
a first electrically conductive component;
a second electrically conductive component; and
a clip electrically coupling the first electrically conductive component to the second electrically conductive component, the clip comprising:
a first portion comprising a first surface, a second surface coupled to the first electrically conductive component, a first thickness between the first surface and the second surface, and a stepped region between the first surface and the second surface such that the second surface has a smaller area than the first surface; and
a second portion coupled to the first portion and the second electrically conductive component, the second portion comprising a third surface, a fourth surface, and a second thickness between the third surface and the fourth surface less than the first thickness, the third surface aligned with the first surface.

10. The semiconductor package of claim 9, further comprising:
a mold material encapsulating at least portions of the first electrically conductive component, the second electrically conductive component, and the clip such that the first surface and the third surface of the clip are exposed.

11. The semiconductor package of claim 9, wherein the first electrically conductive component comprises a first die, a first lead frame, or a first carrier, and
wherein the second electrically conductive component comprises a second die, a second lead frame, or a second carrier.

12. The semiconductor package of claim 9, wherein the clip comprises a third portion coupled to the first portion opposite to the second portion, the third portion comprising a fifth surface, a sixth surface, and the second thickness between the fifth surface and the sixth surface, the fifth surface aligned with the first surface.

13. The semiconductor package of claim 9, wherein the stepped region comprises a single step.

14. The semiconductor package of claim 9, wherein the stepped region comprises a plurality of steps.

15. The semiconductor package of claim 9, wherein the first portion comprises a sloped surface between the first surface and the second surface.

16. The semiconductor package of claim 9, wherein the first portion is pyramid shaped.

17. A method for fabricating a clip for a semiconductor package, the method comprising:
metalworking a single gauge clip precursor to form a dual gauge clip precursor comprising a thin portion and a thick portion; and
coining the thick portion of the dual gauge clip precursor to form a clip comprising a stepped region between a first surface and a second surface opposite to the first surface such that the second surface has a smaller area than the first surface.

18. The method of claim 17, wherein coining the thick portion of the dual gauge clip precursor comprises multiple coining of the thick portion of the dual gauge clip precursor to form a clip comprising a plurality of steps in the stepped region.

19. The method of claim 17, wherein metalworking the single gauge clip precursor to form the dual gauge clip precursor comprises metalworking opposing sides of the single gauge clip precursor to form the thick portion with opposing sloped sidewalls.

20. The method of claim 17, wherein metalworking the single gauge clip precursor to form the dual gauge clip precursor comprises metalworking the single gauge clip precursor to form the thick portion between a first thin portion and a second thin portion larger than the first thin portion.
